(19) United States
(12) Patent Application Publication
(10) Pub. No.: US 2013/0104974 A1
(43) Pub. Date: May 2, 2013

(54) SOLAR CELL AND MANUFACTURING METHOD THEREOF

(71) Applicants: Young-Su Kim, Yongin-si (KR); Dong-Seop Kim, Yongin-si (KR); Doo-Youl Lee, Yongin-si (KR); Young-Jin Kim, Yongin-si (KR); Young-Sang Park, Yongin-si (KR); Chan-Bin Mo, Yongin-si (KR); Sung-Chul Lee, Yongin-si (KR)

(72) Inventors: Young-Su Kim, Yongin-si (KR); Dong-Seop Kim, Yongin-si (KR); Doo-Youl Lee, Yongin-si (KR); Young-Jin Kim, Yongin-si (KR); Young-Sang Park, Yongin-si (KR); Chan-Bin Mo, Yongin-si (KR); Sung-Chul Lee, Yongin-si (KR)

(21) Appl. No.: 13/620,475

(22) Filed: Sep. 14, 2012

(30) Foreign Application Priority Data
Oct. 31, 2011 (KR) 10-2011-0112265

(51) Int. Cl. H01L 31/0216

(52) U.S. Cl. 136/256

(57) ABSTRACT

A solar cell includes a silicon substrate including a front surface for receiving light, and a rear surface opposite the front surface, an emitter diffusion region on the rear surface and doped with a first polarity that is opposite to a polarity of the silicon substrate, a base diffusion region on the rear surface of the substrate and doped with a second polarity that is the same as the polarity of the silicon substrate, and an insulation gap between the emitter diffusion region and the base diffusion region, wherein the base diffusion region has a closed polygonal shape, and wherein the insulation gap is adjacent the base diffusion region.

### RELATED APPLICATIONS

This application claims priority to and the benefit of Korean Patent Application No. 10-2011-0112265 filed in the Korean Intellectual Property Office on Oct. 31, 2011, the entire content of which is incorporated herein by reference.

### BACKGROUND

1. Field

The described technology relates generally to a solar cell and a manufacturing method thereof.

2. Description of the Related Art

A solar cell includes a silicon substrate, and p-doped regions and n-doped regions on a surface of the silicon substrate. When sunlight is applied to the solar cell, that is, when photons enter the substrate, pairs of electrons and holes are generated in the substrate, the generated electrons move to the n-doped regions, and the generated holes move to the p-doped regions. The movement of the electrons and the holes generates the photovoltaic effect, and a potential difference occurs across the ends of the p-n junction. Also, free electrons and holes move to the n-doped and p-doped regions, respectively, to generate a current. Power is generated by the potential difference, and the current is supplied to a load circuit coupled to the solar cell such that the sunlight energy is transformed into electrical energy.

A back contact solar cell includes a substrate, an antireflection layer, doped regions, a protection layer, and contact electrodes. The substrate is a wafer of single crystalline or polycrystalline silicon, and represents a path on which the electrons and the holes move. The front of the substrate is structured, and an antireflection layer made of silicon nitride and silicon oxide is provided on the surface thereof. N-doped regions in a stripe shape and p-doped regions in a stripe shape are alternately arranged at the substrate on the rear surface, and a protection layer is coated on the top part of the rear surface. The protection layer includes via holes that are generated by removing part of areas that are overlapped on the doped regions. The contact electrodes are then electrically connected to the doped regions through the via holes.

The above information disclosed in this Background section is only for enhancement of understanding of the background of the described technology and therefore it may contain information that does not form the prior art that is already known in this country to a person of ordinary skill in the art.

### SUMMARY

Embodiments of the present invention provide a solar cell with great energy efficiency and a manufacturing method thereof.

Embodiments of the present invention provide a solar cell with a low production cost and a manufacturing method thereof.

An exemplary embodiment of the present invention provides a solar cell including a silicon substrate including a front surface for receiving light, and a rear surface opposite the front surface, an emitter diffusion region on the rear surface and doped with a first polarity that is opposite to a polarity of the silicon substrate, a base diffusion region on the rear surface of the substrate and doped with a second polarity that is the same as the polarity of the silicon substrate, and an insulation gap between the emitter diffusion region and the base diffusion region, wherein the base diffusion region has a closed polygonal shape, and wherein the insulation gap is adjacent the base diffusion region.

A width of the insulation gap may be equal to or less than 100 μm.

The emitter diffusion region may be formed by using a screen printing method.

The screen printing method may use a screen on which an emulsion pattern is formed and a paste, the paste may show a spread phenomenon from the emitter diffusion region toward the base diffusion region, and the emitter diffusion region may be spaced from the base diffusion region.

The emitter diffusion region may be formed by using an implant method.

A width of the insulation gap may be equal to or greater than 50 μm and may be equal to or less than 100 μm.

The emitter diffusion region may be formed by using a screen printing method.

An area of the emitter diffusion region may be greater than an area of the base diffusion region.

An area of the emitter diffusion region may be greater than 80 percent of an area of the rear surface.

A width of the insulation gap may be equal to or less than 100 μm.

A width of the insulation gap may be equal to or greater than 50 μm and may be equal to or less than 100 μm.

The solar cell may further include an insulation film on the rear surface, and a base via hole having an area that is equal to or less than an area of the base diffusion region may be in the base diffusion region of the insulation film.

The base diffusion region may further include a first base diffusion region, and a second base diffusion region near the first base diffusion region, and the insulation gap may have an auxiliary insulation gap that extends in a direction of the second base diffusion region from the first base diffusion region.

The solar cell may further include an insulation film on the rear surface, and a base contact electrode including a stem in a base via hole exposing at least a portion of the base diffusion region, and an extending part extending over the insulation film at the stem, and overlapping the auxiliary insulation gap.

A width of the auxiliary insulation gap may be greater than a width of a main insulation gap of the insulation gap.

The width of the auxiliary insulation gap may be equal to or less than a sum of a width of the first base diffusion region and twice the width of the main insulation gap.

The width of the auxiliary insulation gap may be equal to or less than a sum of a width of the first base diffusion region and 200 μm.

The solar cell may further include a plurality of main insulation gaps, and a plurality of auxiliary insulation gaps that are continuously located between one of the main insulation gaps adjacent the first base diffusion region and another one of the main insulation gaps adjacent the second base diffusion region.

The solar cell may further include a plurality of main insulation gaps, and a plurality of auxiliary insulation gaps that are discontinuously located between one of the main insulation gaps adjacent the first base diffusion region and another one of the main insulation gaps adjacent the second base diffusion region.

The solar cell may further include a plurality of emitter diffusion regions, and the auxiliary insulation gap may be between neighboring ones of the emitter diffusion regions.

According to an exemplary embodiment of the present invention, when the insulation gap is provided between the base diffusion region and the emitter diffusion region, usage efficiency of sunlight by the solar cell may be increased. Further, the methods for reducing the production cost may be used to reduce the production cost.

### BRIEF DESCRIPTION OF THE DRAWINGS

FIG. 1A to FIG. 1C respectively show a plan view, a cross-sectional view taken along the line I(B)-I(B)′ of FIG. 1A, and a perspective view of a rear surface of a back contact solar cell including diffusion regions, via holes, and contact electrodes, according to an exemplary embodiment of the present invention.

FIG. 1D shows a relationship a main insulation gap and an auxiliary insulation gap according to a modified embodiment of the present invention.

FIG. 2A and FIG. 2B show a plan view of a unit cell used for a simulation for finding an appropriate width and range of a main insulation gap, and a table of various widths and lengths applicable to the unit cell, respectively.

FIG. 3A and FIG. 3B show a graph and a table of simulation results for showing relationships between widths of a main insulation gap and current densities of a solar cell, respectively.

FIG. 4A to FIG. 4C respectively show a plan view, a cross-sectional view taken along the line IV-IV′ of FIG. 4A, and a cross-sectional view of a rear surface and a cross-sectional view of a screen for indicating changes of a width of an insulation gap relating to an ink spreading phenomenon during a screen printing process.

FIG. 5A and FIG. 5B respectively show a plan view and a cross-sectional view taken along the line V-V′ of FIG. 5A of a rear surface of a silicon substrate on which boron-doped silicate glass is coated.

FIG. 6A and FIG. 6B show a plan view and a cross-sectional view taken along the line VI-VI′ of FIG. 6A of a rear surface of a substrate on which silicate glass is coated while the silicate glass is not doped on a rear surface of a substrate of the embodiment shown in FIG. 5A and FIG. 5B, respectively.

FIG. 7 shows a cross-sectional view of a substrate on which silicate glass is coated while the silicate glass is doped on the rear surface of the substrate of the embodiment shown in FIG. 6A and FIG. 6B.

FIG. 8 shows a cross-sectional view of a substrate when a substrate of the embodiment shown in FIG. 7 undergoes a heat treatment.

FIG. 9A and FIG. 9B show a plan view and a cross-sectional view taken along the line IX-IX′ of FIG. 9A of a rear surface of a substrate shown of the embodiment shown in FIG. 8 from which silicate glass is removed, respectively.

FIG. 10A and FIG. 10B show a plan view and a cross-sectional view taken along the line X-X′ of FIG. 10A of a rear surface of a substrate showing that an insulation film and via holes are formed on the top of the rear surface of the substrate shown in FIG. 9A and FIG. 9B, respectively.

FIG. 11A and FIG. 11B show plan views of a hard mask for forming base and emitter diffusion regions.

### DETAILED DESCRIPTION

To improve usage efficiency of light energy of the solar cell, the electrons and the holes in the substrate should travel a short distance to reach the n-doped regions and the p-doped regions. For this purpose, it is desirable for pitches of the doped regions, that is, a distance between one n-doped region in the stripe shape and a p-doped region that is near the n-doped region, to be short. However, it is difficult to form the doped regions with very narrow pitches by using solar cell manufacturing methods such as screen printing or doping an oxidized silicon coating, which is available with a relatively low production cost. Therefore, a solar cell with doped regions for reducing a moving distance of the electrons and the holes, and a method for manufacturing the solar cell with a low cost, may be desired.

When the doped regions meet each other with opposite polarities, the pitches of the doped regions may be reduced. However, a shunt path for generating an undesired closed circuit may be generated at the part where the doped regions meet to reduce the usage efficiency of the solar cell energy. Accordingly, a solar cell in which the regions that are doped with opposite polarities are arranged with a gap therebetween, and a method for manufacturing the solar cell may be desired.

A method for manufacturing a solar cell according to an exemplary embodiment of the present invention will now be described with reference to accompanying drawings. Throughout the drawings and detailed description of the present specification, like reference numerals indicate like configurations. Also, various numerical values are disclosed in the embodiment, but do not restrict the claims when they are not described in the claims.

According to an exemplary embodiment of the present invention, a side of a silicon substrate includes base diffusion regions, emitter diffusion regions, and insulation gaps between the base diffusion regions and the emitter diffusion regions. The respective base diffusion regions have closed polygon shapes, and are independently positioned from other neighboring base diffusion regions. The respective insulation gaps include a main insulation gap between the emitter diffusion region and the base diffusion region, and an auxiliary insulation gap that is extended toward a neighboring base diffusion region in the main insulation gap.

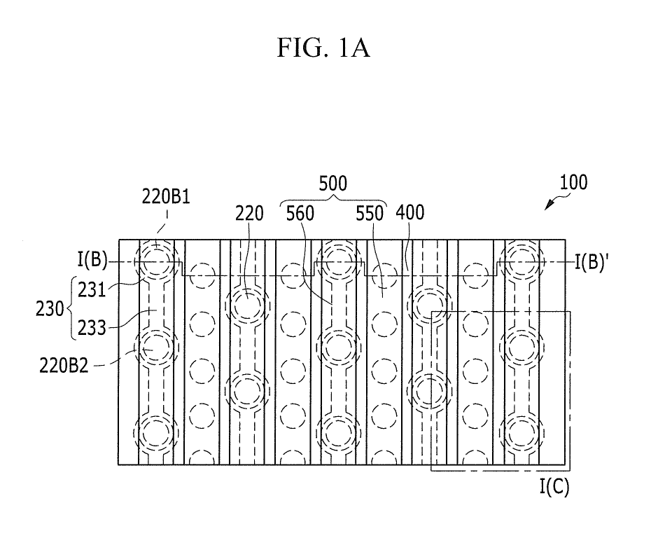

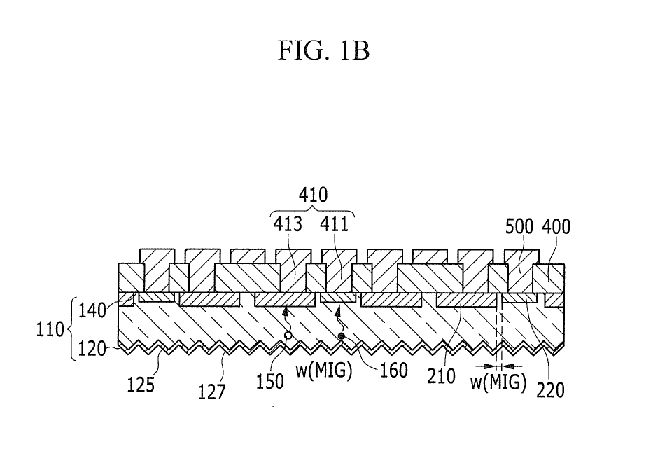

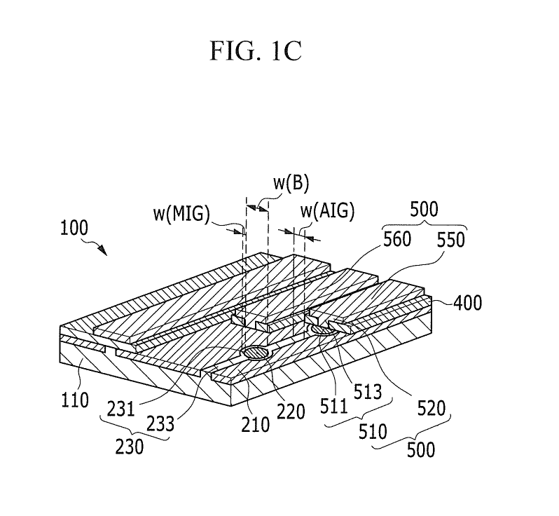

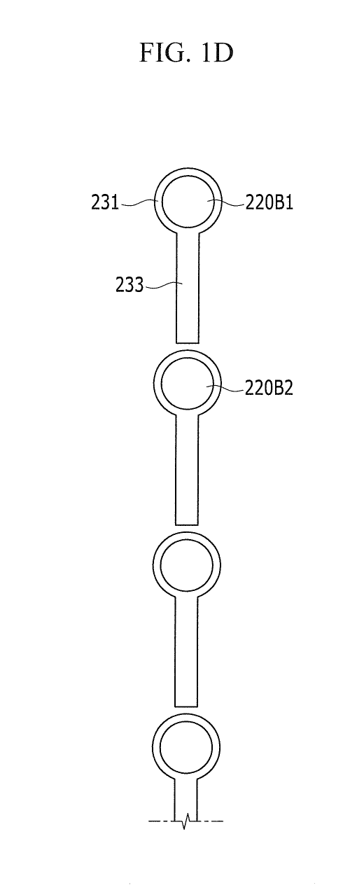

FIG. 1A shows a plan view of a rear surface of a back contact solar cell including diffusion regions (e.g., doped regions), via holes, and contact electrodes according to an exemplary embodiment of the present invention. FIG. 1B shows a cross-sectional view of a back contact solar cell taken along the line I(B)-I(B)′ shown in FIG. 1A. FIG. 1C shows a partial perspective view of a back contact solar cell, and shows an internal part of a solar cell by magnifying the I(C) area of FIG. 1A with an insulation film of the solar cell and a contact electrode not shown.

The back contact solar cell 100 of the present embodiment includes a silicon substrate 110 having a front surface 120 and a rear surface 140, and has a configuration in which emitter diffusion regions 210 and base diffusion regions 220 are arranged on the rear surface 140 of the silicon substrate 110. The back contact solar cell 100 includes an insulation film 400 provided on the rear surface 140 of the silicon substrate 110, and a contact electrode 500 passing through the insulation film 400 and contacting the rear surface 140. The silicon substrate 110 may be a single crystal silicon wafer with a (1, 1, 0) lattice structure on which one or more materials that are selected from among n-type phosphorus (P), arsenic (As), antimony (Sb), and a mixture thereof are doped in a thin manner as dopants. For example, the substrate may be an n-type silicon substrate to which atoms are doped with a concentration of 1×10¹⁵ cm⁻³.

The front surface 120 of the silicon substrate 110, which is for receiving light (e.g., sunlight), represents a structured front surface 125, and a general antireflection film 127 provided on the structured front surface 125. The rear surface 140 of the silicon substrate 110 includes emitter diffusion regions 210 in which p-type group III dopants, such as boron (B), are diffused and base diffusion regions 220 in which n-type group V dopants, such as phosphorus (P), are diffused. The emitter diffusion regions 210 are distanced from the base diffusion regions 220. The insulation film 400 includes via holes 410 for exposing parts of the emitter and base diffusion regions 210 and 220 provided on the rear surface 140. The contact electrodes 500 made of conductive materials, such as aluminum (Al), copper (Cu), nickel (Ni), tungsten (W), or titanium (Ti), are filled in the via holes 410. The via holes 410 and the contact electrodes 500 are classified as emitter via holes 411 and emitter contact electrodes 550 provided in the emitter diffusion regions 210 and base via holes 413 and base contact electrodes 560 provided in the base diffusion regions 220, and they are uniformly provided in an entire area of the rear surface 140 so that holes provided in the emitter diffusion region 210 and electrons provided in the base diffusion regions 220 may be efficiently moved to an external circuit (not shown).

Embodiments of the present invention include an increased p-doped area for receiving holes 150, that is, the emitter diffusion region 210, so that the holes 150 that are generated by sunlight and are provided in the n-type substrate are not recombined with electrons 160 but are moved to the emitter contact electrode 550. Therefore, the emitter diffusion region 210 has a pattern that is provided in most of the area of the rear surface 140. In another method according to an embodiment of the present invention, when the solar cell is manufactured with a p-type silicon substrate that is doped with p-type dopants with a low concentration, the emitter diffusion region 210 in the wide area becomes an n-doped area. For ease of description, the exemplary embodiments of the current specification will describe an n-type substrate based solar cell and a manufacturing method thereof.

Referring to FIG. 1A to FIG. 1C, the emitter diffusion regions 210 of the silicon substrate 110 represent a plurality of emitter diffusion regions 210 that are separated from each other. An insulation gap 230 including a main insulation gap 231 and an auxiliary insulation gap 233 is between neighboring emitter diffusion regions 210. The main insulation gap 231 represents a region between the emitter diffusion region 210 and the base diffusion region 220 in a configuration in which a base diffusion region 220 is between neighboring emitter diffusion regions 210. The auxiliary insulation gap 233 represents a region between the emitter diffusion regions 210 in a configuration in which there is no base diffusion region between neighboring emitter diffusion regions 210. The auxiliary insulation gap 233 may extend (e.g., protrude) in a direction of a second base diffusion region 220B2, which is near a first base diffusion region 220B1, in the main insulation gap 231 that is near the first base diffusion region 220B1.

The main insulation gap 231 prevents formation of a shunt path, that is, formation of a closed circuit, by combination of holes 150 of the emitter diffusion region 210 and electrons 160 of the base diffusion region 220. When a small shunt path is formed, many more holes 150 or electrons 160 may be provided to an external circuit (not shown) through the contact electrodes 500 so sunlight usage efficiency of the solar cell 100 may be increased. The shunt path is reduced when a width (w(MIG)) of the main insulation gap 231 is increased. However, when the width (w(MIG)) of the main insulation gap 231 is increased, a distributed area of the emitter diffusion region 210 is reduced so the sunlight usage efficiency of the solar cell 100 may be reduced. Accordingly, embodiments of the present invention provide an appropriate range of the width (w(MIG)) of the insulation gap 231 in consideration that the width (w(MIG)) of the main insulation gap 231 may influence efficiency of the solar cell. In this instance, the range of the width of the insulation gap may be set by those having suitable skills in manufacturing the solar cell.

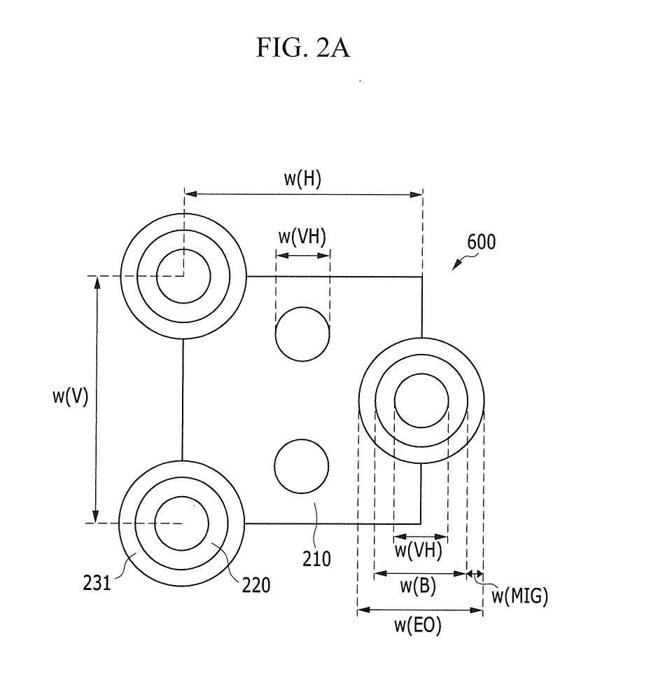

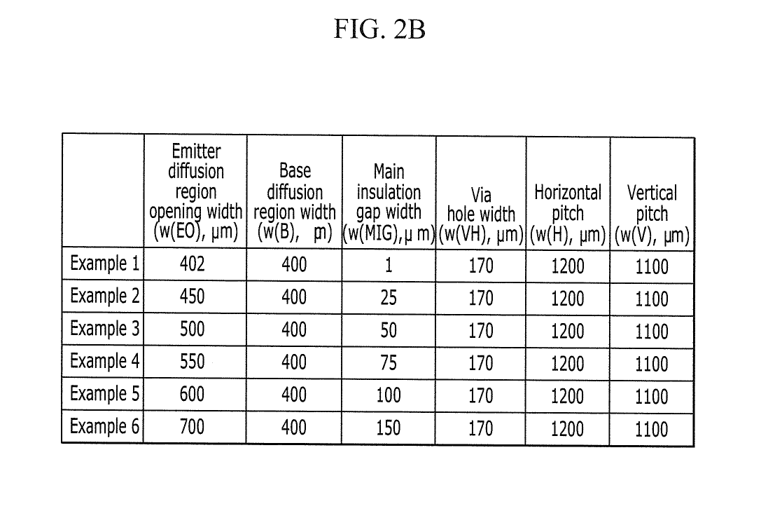

FIG. 2A shows a top plan view of a unit cell 600 used for a simulation for checking the range of the width of the main insulation gap 231. FIG. 2B shows a table of various widths and lengths applied to the unit cell 600 of FIG. 2A. The unit cell 600 shown in FIG. 2A is configured by regularly arranging the emitter diffusion regions 210, the base diffusion regions 220, the main insulation gaps 231, and the via holes 410 that are shown in FIGS. 1A to 1C on the rear surface 140 of the solar cell substrate. A vertical pitch (w(V)) and a horizontal pitch (w(H)) of the unit cell 600 shown in FIG. 2A represent distances at which base diffusion regions 220 are repeated in the vertical direction and the horizontal direction of the unit cell. Regarding the horizontal pitch (w(H)), the neighboring base diffusion regions 220 are moved by half the distance of the vertical pitch (w(V)). The respective simulated examples include, in common, an n-type substrate on which boron atoms are distributed with a concentration of 1.56×10¹⁵ cm⁻³, an emitter diffusion region 210 and a base diffusion region 220 with sheet resistance of 272 ohm/cm², and a main insulation gap 231 with practically infinite shunt resistance. Referring to FIG. 2B, widths (w(B)) of the base diffusion regions 220 of the simulated examples are the same and the widths (w(MIG)) of the main insulation gap 231 are changeable in various manners.

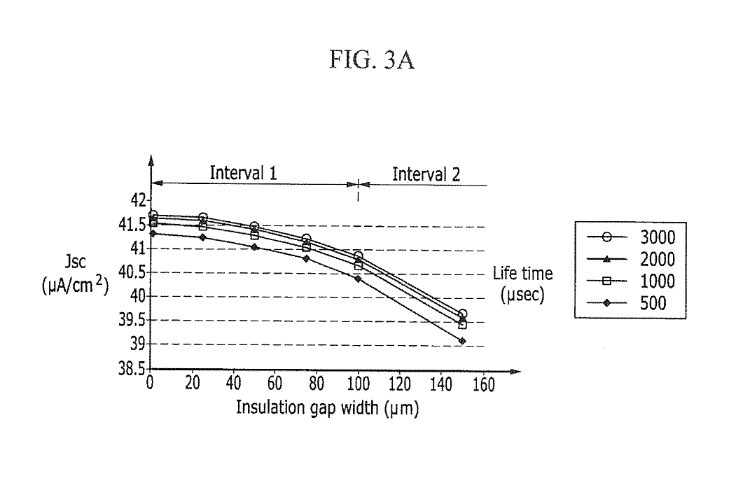

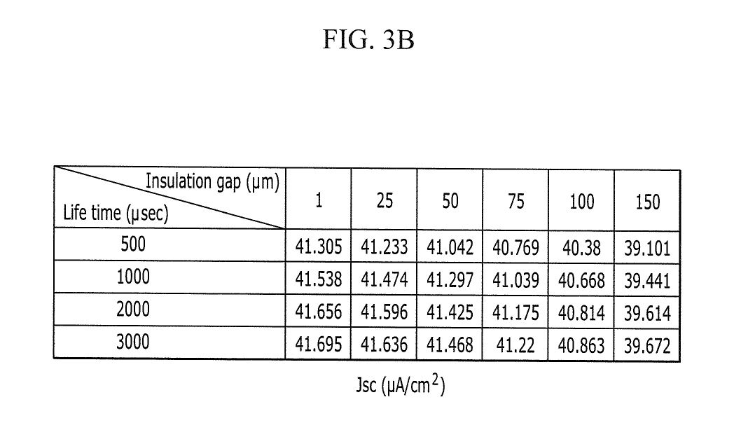

FIG. 3A shows a simulation graph of a relationship between widths of the main insulation gap 231 and short circuit currents (Jsc) of the solar cell for lifetimes of various charge carriers. FIG. 3B shows a table for short circuit current values together with the main insulation gaps 231 and the lifetimes of charge carriers shown in FIG. 3A. The charge carriers signify electrons or holes that are generated by sunlight and are moved in the substrate. The simulation results are based on the conditions shown in FIG. 2A and FIG. 2B. Particularly, it must be noted that an influence of shunt resistance is not considered in the simulation because the condition in which shunt resistance has the same practically infinite value for the widths of various insulation gaps is used.

According to the simulation results shown in FIG. 3A and FIG. 3B, the short circuit current (Jsc) of the solar cell is gradually reduced when the width of the insulation gap is increased during an interval (Interval 1) in which the width of the insulation gap is 1 μm to 100 μm, and the short circuit current (Jsc) of the solar cell is steeply reduced as the width of the insulation gap during an interval (Interval 2) in which the width of the insulation gap is greater than 100 μm. Therefore, according to the present embodiment, the width of the insulation gap to be greater than 0 μm and less than or equal to 100 μm.

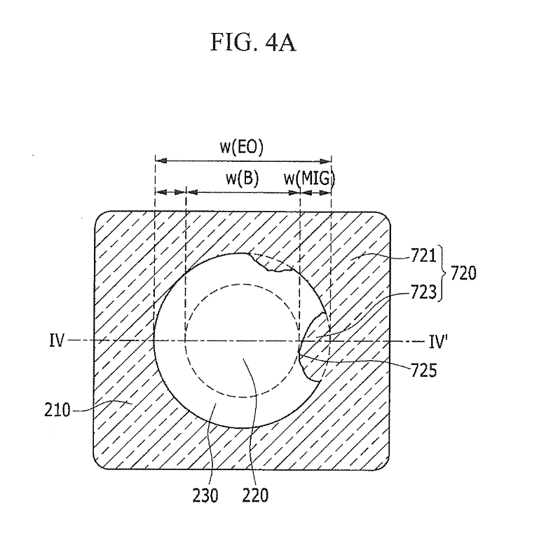

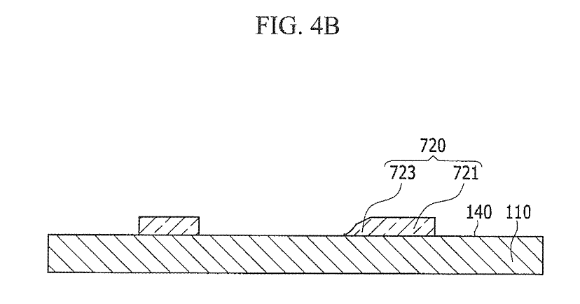

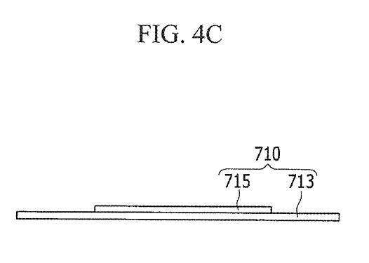

When screen printing is used for forming the diffusion regions, the width of the main insulation gap may be established in consideration of a spread phenomenon of an ink that is screen-printed on the rear surface of the substrate. FIG. 4A to FIG. 4C show a spread phenomenon of an ink in a screen printing process, and changes of the width of the insulation gap relating to the spread phenomenon. FIG. 4A shows a magnified plan view of a rear surface 140 of a silicon substrate 110 to which a paste 720 is discharged by screen printing. FIG. 4B shows a cross-sectional view of a silicon substrate with respect to the line IV-IV′ of FIG. 4A. FIG. 4C shows a cross-sectional view of a screen net used for a screen printing process allowing a distribution of a paste shown in FIG. 4A.

The screen printing provides paste on an emulsion pattern (e.g., a predetermined emulsion pattern) 715 and a screen 710 with a net 713 and presses the screen 710 with a squeegee (not shown) so that the paste may pass through a part other than the emulsion pattern 715 on the screen 710 and may be discharged on the surface of a printed material (e.g., a rear surface of the silicon substrate). The emulsion pattern 715 may be formed to be substantially equivalent to the shape of the area that is printed on the printed material. For example, the emulsion pattern 715 may be formed to be substantially equivalent to the shape of the emitter diffusion region 210 that is formed of boron silicate glass (BSG) that is discharged on the rear surface 140 of the silicon substrate 110. The BSG 720 that is discharged on the rear surface 140 of the silicon substrate 110 may be a paste 721 having a distribution that is very close to the shape of the emulsion pattern 715. Differing from this, the discharged BSG 720 may be paste 723 having a distribution that is different from the shape of the emulsion pattern 715. The shape of the emulsion pattern 715 is equivalent to the shape (e.g., the predetermined shape) of the emitter diffusion region 210 so the spread phenomenon of the paste (BSG) is generated in an insulation gap (e.g., a predetermined insulation gap) and the width of the insulation gap 730 may be reduced.

When the BSG is spread to reach the base diffusion region (e.g., the predetermined base diffusion region) 220, the emitter diffusion region 210 may have a part 725 contacting the base diffusion region 220. A shunt path is formed at the part 725 where the diffusion regions 210 and 220 with two opposite charges meet so the sunlight usage efficiency of the solar cell may be reduced. Therefore, the width of the insulation gap may be set in consideration of the range of the width of the spreading paste (BSG) during the screen printing process. The range of the width of the spreading paste (BSG) may be set by a process margin of the screen printing process. Generally considering that the process margin of the screen printing process used for manufacturing the solar cell is 50 μm and also considering the relationship between the width of the insulation gap and the short circuit current described with reference to FIG. 2A to FIG. 3B, embodiments of the present invention have the width (w(EO)) of the emulsion pattern 715 of the screen mask used for forming an emitter diffusion region greater than the width (w(B)) of the base diffusion region 210 by more than 50 μm and less than 100 μm, and the width (w(MIG)) of the insulation gap formed by the screen printing process using the screen mask greater than 0 μm and equal to or less than 100 μm.

The solar cell includes an auxiliary insulation gap that is protruded (e.g., extends) in a direction of a neighboring base diffusion region from the main insulation gap near the base diffusion region. The auxiliary insulation gap may prevent contact electrodes with opposite polarities and the diffusion region from being electrically connected with each other.

FIG. 1C shows a partial perspective view of a solar cell 100 in which an insulation film 400 is located on an auxiliary insulation gap 233, and a contact electrode 500 is located on the insulation film 400. The contact electrode 500 includes an emitter contact electrode 550 contacting the emitter diffusion region 210 and transmitting the holes to an external circuit, and a base contact electrode 560 contacting the base diffusion region 220 and transmitting the electrons to the external circuit.

The emitter and base contact electrodes 550 and 560 respectively include a stem 510 that is filled in the via hole 410 in the insulation film 400, and an extensive part (e.g., extending part) 520 that is coupled to the stem 510 and is extended over the insulation film 400. The stem 510 includes a diffusion region contact end 511 contacting the diffusion regions 210 and 220. An area of a cross-section that is in parallel with the substrate 110 of the stem 510, that is, an area of the horizontal cross-section, may be substantially equivalent irrespective of kinds of the diffusion regions in which the stem 510 is provided (i.e., emitter and base diffusion regions), and it may be set in consideration of the areas of the diffusion regions 210 and 220. Particularly, the area of the base diffusion region 220 is relatively very much less than the area of the emitter diffusion region 210 so the area of the horizontal cross-section of the stem 510 may be less than the area of the base diffusion region 220.

The extensive part 520 is coupled to an opposite end 513 of the diffusion region contact end 511 of the stem 510, and is widely spread on the insulation film 400 so as to reduce its resistance. In detail, the extensive part 520 may be positioned such that the width of the extensive part 520 may be greater than the width of the horizontal cross-section of the stem 510 and the same may be provided as close as possible to the neighboring extensive part 520. The extensive part 520 is electrically independent from the diffusion region and has a polarity that is opposite the polarity of the diffusion region that is next to the extensive part 520. For example, the base contact electrode 560 shown in FIG. 1A to FIG. 1C is electrically independent from the emitter diffusion region 210 that is provided below the extensive part 520 of the base contact electrode 560. The insulation film 400 is provided between the base contact electrode 560 and the emitter diffusion region 210, and when the insulation film 400 has a pin hole or a part of the insulation film 400 is abnormally thin, a shunt path may occur between the base contact electrode 560 and the emitter diffusion electrode 210.

However, when the insulation gap 230 is below the part of the insulation film 400 that is abnormally thin or has a defect (e.g., a pin hole), generation of the shunt path may be prevented. The insulation gap 230 may be a main insulation gap 231 between diffusion regions with opposite polarities (e.g., the emitter diffusion region and the base diffusion region). According to another exemplary embodiment, the insulation gap 230 may be an auxiliary insulation gap 233 between the diffusion regions (e.g., emitter diffusion region or base diffusion region) with the same polarity or between the neighboring main insulation gaps 231.

In the present embodiment, the width (w(AIG)) of the auxiliary insulation gap 233 is set to be equivalent to the width (w(MIG)) of the main insulation gap 231 so the area of the emitter diffusion region 210 may be great. According to another exemplary embodiment, the width (w(AIG)) of the auxiliary insulation gap 233 may be set to be equal to a sum of the width (w(B)) of the base diffusion region 220 neighboring the auxiliary insulation gap 233 and the widths (w(MIG)) of the two main insulation gaps 231 near the base diffusion region 220 to reduce generation of the shunt path. Therefore, according to the present embodiment, the range of the width (w(AIG)) of the auxiliary insulation gap 233 may satisfy Equation 1.

w(B)≦w(AIG)≦w(B)+2w(MIG)

As shown in FIG. 1A to FIG. 1C, according to embodiments of the present invention, the auxiliary insulation gap 233 may have a shape that is coupled to the main insulation gap 231, or the auxiliary insulation gap 233 may be unconnected to the main insulation gap 231 and independently positioned. Further, the auxiliary insulation gap 233 may be continuously coupled between the main insulation gaps near first and second base diffusion regions. Also, as shown in FIG. 1D, the auxiliary insulation gap 233 may be discontinuously coupled between the main insulation gaps 231 near the first base diffusion region 220B1 and second base diffusion region 220B2.

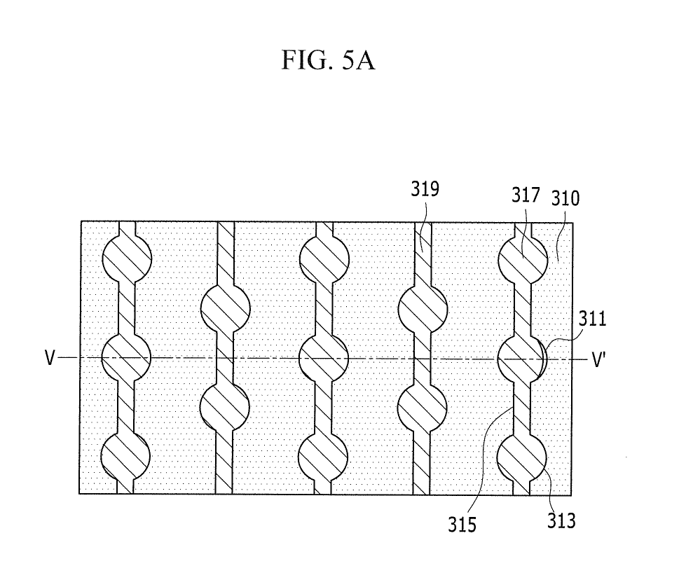

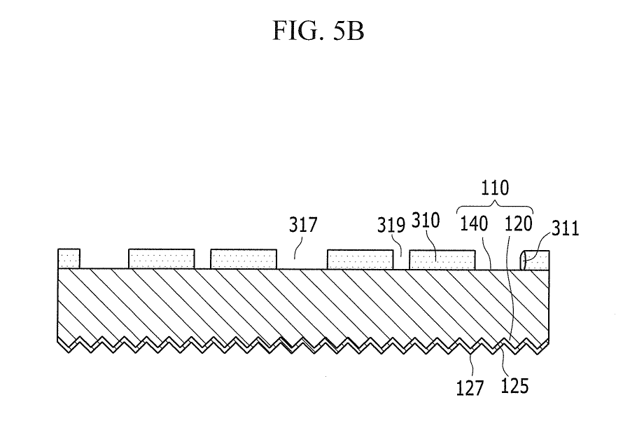

FIG. 5A to FIG. 10B show plan views and cross-sectional views of stages for manufacturing diffusion regions (e.g., doped regions), via holes, and contact electrodes of a back contact solar cell according to an exemplary embodiment.

FIG. 5A shows a partial plan view of a rear surface of a silicon substrate when a BSG 310 is coated on a rear surface 140 of a substrate. FIG. 5B shows a cross-sectional view of a silicon substrate with respect to the line V-V′ of FIG. 5A.

The substrate 110 may be an n-type silicon substrate that is doped with phosphorus atoms with the concentration of 1×10¹⁵ cm⁻³ and that is substantially 150 μm to 170 μm thick. A front surface 120 of the substrate 110 to which sunlight is applied may be a structured front surface 125 that is structured through etching by use of potassium hydroxide (KOH) and isopropyl alcohol. The structured front surface 125 includes a front surface field layer (not shown) formed by injection and activation of phosphorus ions with a low dose of substantially 1.0×10¹³ cm⁻² to 7×10¹⁵ cm⁻². An antireflection film 127 configured with a silicon oxide film that is formed when silicon is oxidized in a chamber at substantially 900° C. for 45 to 50 minutes when flowing oxygen gas and hydrogen gas with a volume ratio of about 3:2, and a silicon nitride film that is formed on the silicon oxide film by a conventional chemical vapor deposition method, may be formed on the front surface field layer. The structured front surface 125 and the antireflection film 127 may be formed when the BSG 310 is coated on the rear surface 140 of the substrate, and the same may be formed when another layer or elements are formed on the rear surface of the substrate.

The rear surface 140 of the substrate 110 represents a flat surface from which crystallization defects, incised defects, native oxides, or unnecessary impurities are substantially removed, and which is then polished. The BSG 310 is formed on the rear surface 140 of the substrate to be substantially 1000 Å thick and to have a pattern (e.g., a predetermined pattern) through a screen printing, inkjetting, or photolithography process. When the BSG 310 is coated on the rear surface 140 through the screen printing or inkjetting process, an edge of the coated BSG 310 may be different from the pattern according to the spread phenomenon. For example, a spread unit 311 of the BSG 310 (e.g., an area of the BSG resulting from a spread phenomenon) may reduce a distance between the neighboring areas of BSG 310.

The BSG 310 that is coated on the n-type substrate 110 functions so that a part of the rear surface 140 covered by the BSG 310 becomes a p-doped region, that is, the emitter diffusion region, according to a heat treatment process to be described. As described above, as the emitter diffusion region becomes wider, the holes are efficiently transmitted to the external circuit so the doped BSG 310 has a pattern that is provided in the widest part of the entire area of the rear surface 140. For example, the area of the coated BSG 310 may be greater than 80 percent of the entire area of the rear surface 140.

Referring to FIG. 5A, the coated BSG 310 includes curved lines 313 and straight lines 315 extending between neighboring curved lines 313. One curved line 313 (e.g., of a base diffusion region body) and another curved line 313 (e.g., of a neighboring emitter diffusion region body) define a pre-main insulation gap 317. One straight line 315 (e.g., of a base diffusion region body) and a corresponding other straight line 315 (e.g., of the neighboring emitter diffusion region body) define a pre-auxiliary insulation gap 319. The curved line 313 and the straight line 315 may also respectively be the edges of the main insulation gap 231 and the auxiliary insulation gap 233 on the rear surface. A width of the pre-main insulation gap 317 is greater than the width of the pre-auxiliary insulation gap 319.

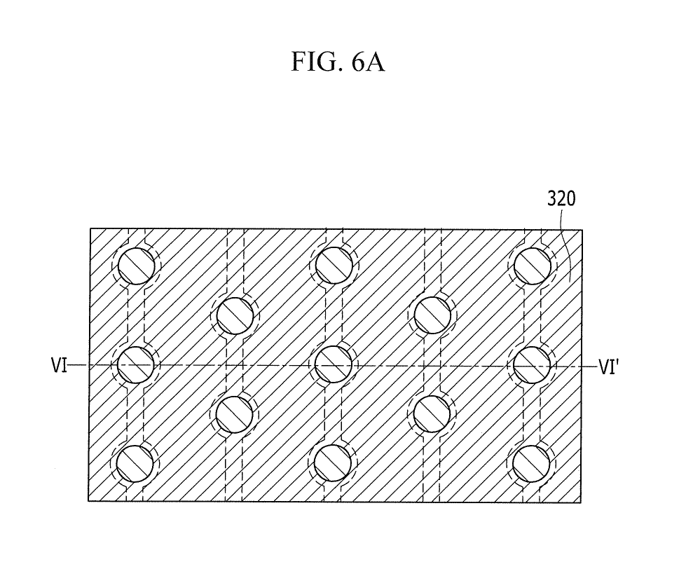

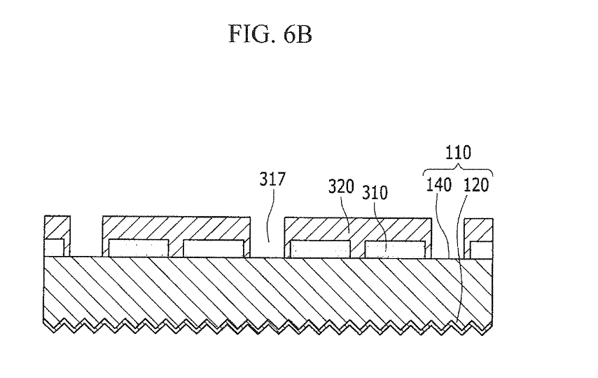

FIG. 6A shows a partial plan view of a rear surface of a silicon substrate when an undoped silicate glass (USG) is coated on the rear surface of the substrate of the embodiment shown in FIG. 5A and FIG. 5B. FIG. 6B shows a cross-sectional view of a silicon substrate with respect to the line VI-VI′ of FIG. 6A. The USG 320 is formed to be substantially 2000 Å thick and to have a pattern (e.g., a predetermined pattern) on the rear surface 140 of the substrate on which the BSG 310 is coated according to the screen printing, inkjetting, or photolithography process. The pattern of the USG 320 is provided on the entire part of the rear surface of the pre-main insulation gap 317 except an enter portion, and the pattern of the USG 320 covers the entire BSG 310. In FIG. 6A, the edges of the BSG 310 covered by the USG 320 are shown by dotted lines.

The pattern of the USG 320 is separated from the curved lines 313 of the BSG 310 with a gap (e.g., a predetermined gap) in a central direction of the pre-main insulation gap 317, and the pattern of the USG 320 has a closed polygonal shape. A part of the silicon substrate 110 corresponding to the closed polygon shape becomes an n-doped region, that is, the base diffusion region according to a process for coating phosphorus silicate glass (PSG) to be described. FIG. 6A shows a circle as an example of the closed polygon shape, and other forms of the closed polygon shape are possible, which will be easily understood by a person of ordinary skill in the art.

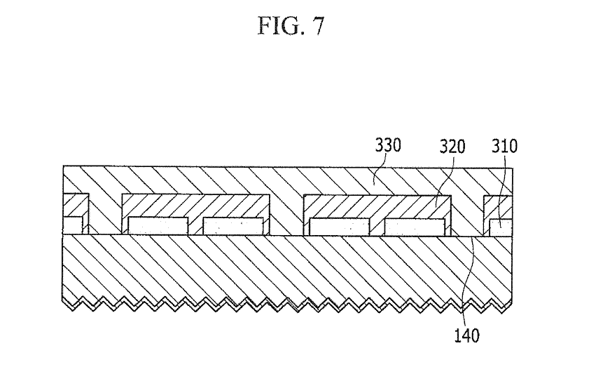

FIG. 7 shows a cross-sectional view of a silicon substrate when the PSG 330 is coated on the rear surface 140 of the substrate of the embodiment shown in FIG. 6A and FIG. 6B. The PSG 330 of the present embodiment is provided to be substantially 1000 Å thick on the entire rear surface of the substrate through the screen printing, inkjetting, or photolithography process, and it covers a part of the rear surface 140 that is not covered by the USG 320 and the BSG 310.

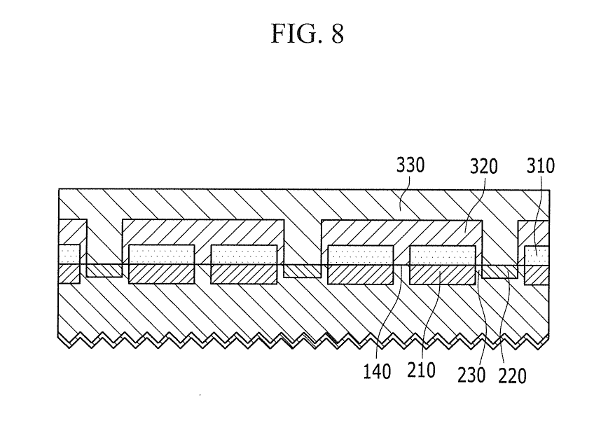

FIG. 8 shows a cross-sectional view of a silicon substrate when the substrate of the embodiment shown in FIG. 7 undergoes a heat treatment process. The heat treatment exemplarily controls the temperature of the substrate to be at substantially 1000° C. and maintains it for about an hour. After the heat treatment process, the part contacting the BSG 310 on the rear surface 140 of the substrate becomes a p-doped region, that is, the emitter diffusion region 210, and the part contacting the PSG 330 becomes an n-doped region, that is, the base diffusion region 220. The part contacting the USG 320 becomes the insulation gap 230.

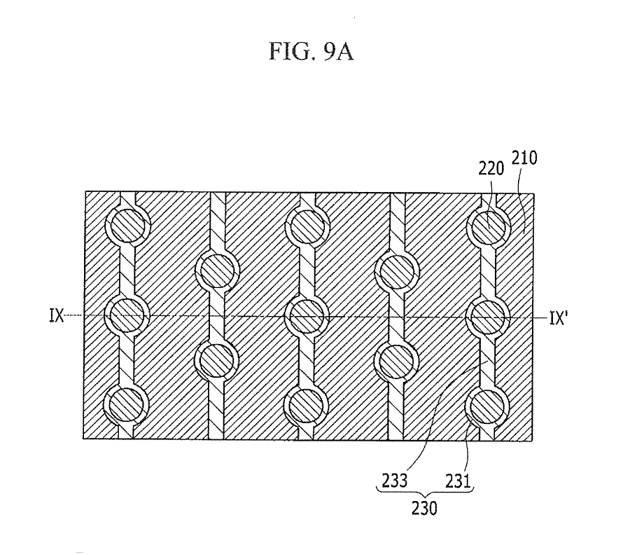

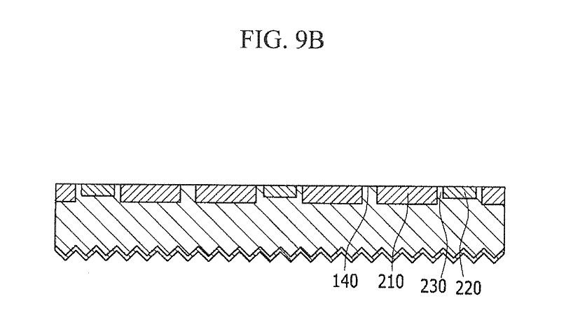

FIG. 9A shows a partial plan view of a rear surface 140 of a silicon substrate when silicate glass 310, 320, and 330 is removed from the substrate of the embodiment shown in FIG. 8. FIG. 9B shows a cross-sectional view of a silicon substrate with respect to the line IX-IX′ of FIG. 9A. For example, the silicate glass such as the BSG 310, the USG 320, and the PSG 330 shown in FIG. 8 is removed with a solution of hydrogen fluoride (HF) and deionized water that are mixed at a ratio of 1:10.

The rear surface 140 of the silicon substrate includes emitter diffusion regions 210 over the widest area of the entire rear surface, base diffusion regions 220 between neighboring emitter diffusion regions 210, and an insulation gap 230. As described above, the insulation gap 230 includes a main insulation gap 231 between the diffusion regions 210 and 220 with opposite polarities and reduces generation of a shunt path, and an auxiliary insulation gap 233 between the diffusion regions (e.g., emitter diffusion regions) with the same polarity, which prevents electrical connection between the diffusion region and the contact electrode over the diffusion region.

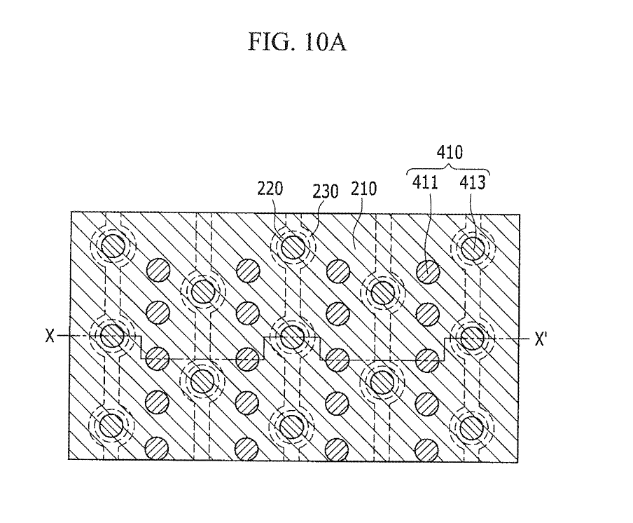

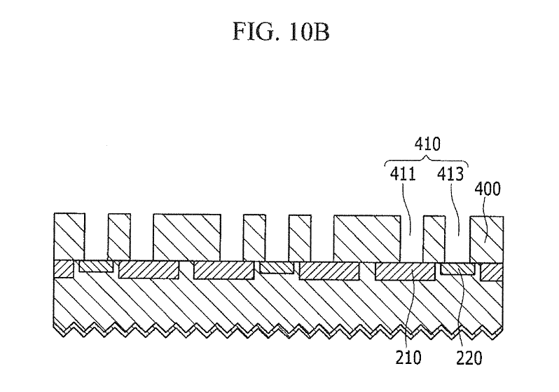

FIG. 10A shows a partial plan view of a rear surface of a silicon substrate when an insulation film 400 and via holes 410 are formed on a rear surface of a substrate of the embodiment shown in FIG. 9A to 9B. FIG. 10B shows a cross-sectional view of a silicon substrate with respect to the line X-X′ of FIG. 10A. The insulation film 400 is formed to be substantially 1500 Å thick on the rear surface 140 of the silicon substrate by using a layer or layers selected from the USG, the silicon oxide layer, the silicon nitride layer, or a stacked structure thereof.

The via holes, through which parts of the emitter and base diffusion regions are exposed, are formed when an etch resist is coated on the insulation film 400 and the etch resist is etched according to the screen printing, inkjetting, or photolithography method. The via holes include emitter via holes 411 formed in the emitter diffusion region 210 and base via hole 413 formed in the base diffusion region. The emitter via holes 411 may be regularly distanced from each other in the emitter diffusion region 210. The base via holes 413 may be in different base diffusion regions 220. In FIG. 10A, edges of the emitter diffusion region 210, edges of the base diffusion region 220, and the insulation gaps 230 are covered by the insulation film 400 and are shown with dotted lines.

The via holes 411 and 413 shown in FIG. 10A and FIG. 10B are filled with contact electrodes made of a conductive material. A plan view, a cross-sectional view, and a perspective view of the solar cell in which the contact electrode is formed are equivalent to FIG. 1A to FIG. 1C and corresponding descriptions.

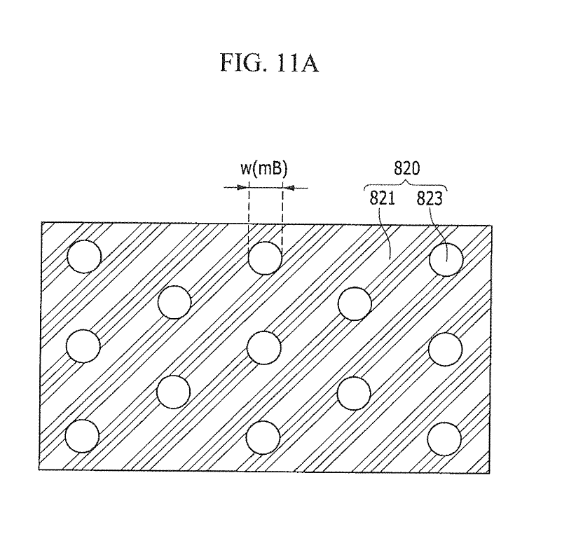

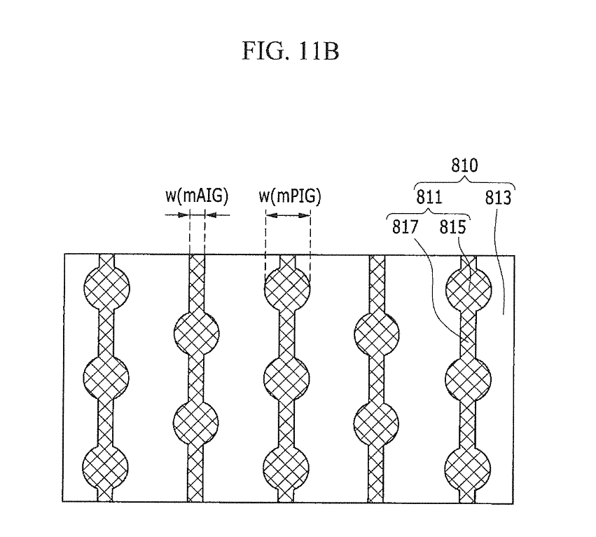

The formation of the diffusion regions 210 and 220 and the insulation gaps 230 by using the screen printing, inkjetting, or photolithography method has been described, and in addition, the diffusion regions 210 and 220 and the insulation gaps 230 may be formed by using an implant process. FIG. 11A and FIG. 11B show plan views of hard masks used for a process for forming diffusion regions (e.g., doped regions) of a back contact solar cell according to an exemplary embodiment. The respective hard masks may be heat-resistant substrates made of graphite or ceramic that are substantially 1 mm thick.

Referring to FIG. 11A, a base hard mask 820 used for a process for forming a base diffusion region on a rear surface of the substrate includes a base ion interceptor 821 and a base ion transmitter 823. The base ion interceptor 821 represents a region for preventing the ions from moving to the substrate when the n-type atoms, such as phosphorus, are implanted on the rear surface of the n-type silicon substrate, and the base ion interceptor 821 corresponds to a part other than the base diffusion region formed on the rear surface of the silicon substrate. The base ion transmitter 823 represents an opening that is generated according to a form (e.g., a predetermined form) so that the n-type atoms may move to the rear surface of the n-type silicon substrate. A shape and a position of the base ion transmitter 823 substantially correspond to a shape and a position of the distanced base diffusion regions to be formed on the silicon substrate. In FIG. 11A, a base ion interceptor 821 is provided between neighboring base ion transmitters 823, and the shapes of the base ion transmitters 823 may be circular having substantially the same width as the width (w(B)) of the base diffusion region formed on the rear surface of the silicon substrate.

Referring to FIG. 11B, an emitter hard mask 810 used for a process for forming an emitter diffusion region on a rear surface of a silicon substrate includes an emitter ion interceptor 811 and an emitter ion transmitter 813. The emitter ion transmitter 813 represents an opening that is formed so that the atoms may move to the silicon substrate when the p-type atoms, such as boron, are implanted on the rear surface of the n-type silicon substrate, and the emitter ion transmitter 813 corresponds to a part of the emitter diffusion region that is formed on the rear surface of the silicon substrate.

The emitter ion interceptor 811 represents a region for preventing the atoms from moving to the silicon substrate, and it corresponds to a part other than the emitter diffusion region formed on the rear surface of the silicon substrate. According to the above-described exemplary embodiments, a part other than the emitter diffusion region on the rear surface of the silicon substrate includes a base diffusion region and an auxiliary insulation gap between a pre-main insulation gap having a main insulation gap that is near the base diffusion region and a neighboring pre-main insulation gap. Therefore, the emitter ion interceptor 811 includes a pre-main insulation gap interceptor 815 corresponding to the pre-main insulation gap and an auxiliary insulation gap interceptor 817 corresponding to the auxiliary insulation gap. The pre-main insulation interceptors 815 are distanced from each other so when they are not connected with each other, it is difficult, if not impossible, to fix their positions on the hard mask. However, the auxiliary insulation gap interceptor 817 couples the neighboring pre-main insulation interceptors 815 so it becomes possible to fix the pre-main insulation interceptors 815 and the auxiliary insulation gap interceptor on the hard mask.

During the implant process, the emitter hard mask 810 is closely attached to the rear surface of the silicon substrate, and the pre-main insulation gap interceptor 815 and the auxiliary insulation gap interceptor 817 of the emitter ion interceptor 811 have substantially the same shape and position of the pre-main insulation gap and the auxiliary insulation gap formed on the rear surface of the silicon substrate. Therefore, the width (w(mPIG)) of the pre-main insulation gap interceptor 815 and the width (w(mAIG)) of the auxiliary insulation gap interceptor 817 shown in FIG. 11B may be equivalent to the opening width (w(EO)) (e.g., w(EO) shown in FIG. 2A) of the emitter diffusion region formed on the rear surface of the silicon substrate and the widths (w(AIG)) of the auxiliary insulation gaps (e.g., w(AIG) shown in FIG. 1C). To form a wide area of the emitter diffusion region, the width (w(mAIG)) of the auxiliary insulation gap interceptor 817 may be less than the width (w(mPIG)) of the pre-main insulation gap interceptor 815.

The width (w(mB)) of the base ion transmitter 823 of the base hard mask 820 is less than the width (w(mPIG)) of the pre-main insulation gap interceptor 815 of the emitter hard mask 810. Further, as described above, in the present embodiment, the range of the width (w(mPIG)) of the pre-main insulation gap satisfies Equation 2 when considering that the base diffusion region 220 and the emitter diffusion region 210 formed on the rear surface of the silicon substrate are distanced by the width of the insulation gap 230, and the sunlight usage efficiency of the substrate is great when the width of the insulation gap 230 is less than 100 μm according to the simulation result described with reference to FIG. 2A to FIG. 3B.

0<w(mPIG))≦w(mB)+200 μm Equation 2

When the solar cell is manufactured by using the implant method, the case of using the masks 810 and 820 for forming the emitter and base diffusion regions has been described, and according to another exemplary embodiment, one diffusion region is formed by using the implant method and another diffusion region is formed by using the screen printing, inkjetting, or chemical vapor deposition method, which will be easily understood by a person skilled in the art.

The exemplary embodiments have exemplified the case of using the n-type silicon substrate, and the p-type silicon substrate may also be used. In that case, the emitter diffusion region represents an n-type impurity diffused region and the base diffusion region represents a p-type impurity diffused region, which will be easily understood by a person skilled in the art.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

What is claimed is:

1. A solar cell comprising:
a silicon substrate comprising:
a front surface for receiving light; and
a rear surface opposite the front surface;
an emitter diffusion region on the rear surface and doped with a first polarity that is opposite to a polarity of the silicon substrate;
a base diffusion region on the rear surface of the substrate and doped with a second polarity that is the same as the polarity of the silicon substrate; and
an insulation gap between the emitter diffusion region and the base diffusion region,
wherein the base diffusion region has a closed polygonal shape, and
wherein the insulation gap is adjacent the base diffusion region.

2. The solar cell of claim 1, wherein a width of the insulation gap is equal to or less than 100 μm.

3. The solar cell of claim 2, wherein the emitter diffusion region is formed by using a screen printing method.

4. The solar cell of claim 3, wherein the screen printing method uses a screen on which an emulsion pattern is formed and a paste,
wherein the paste shows a spread phenomenon from the emitter diffusion region toward the base diffusion region, and
wherein the emitter diffusion region is spaced from the base diffusion region.

5. The solar cell of claim 2, wherein the emitter diffusion region is formed by using an implant method.

6. The solar cell of claim 1, wherein a width of the insulation gap is equal to or greater than 50 μm and is equal to or less than 100 μm.

7. The solar cell of claim 6, wherein the emitter diffusion region is formed by using a screen printing method.

8. The solar cell of claim 1, wherein an area of the emitter diffusion region is greater than an area of the base diffusion region.

9. The solar cell of claim 1, wherein an area of the emitter diffusion region is greater than 80 percent of an area of the rear surface.

10. The solar cell of claim 9, wherein a width of the insulation gap is equal to or less than 100 μm.

11. The solar cell of claim 9, wherein a width of the insulation gap is equal to or greater than 50 μm and is equal to or less than 100 μm.

12. The solar cell of claim 1, further comprising an insulation film on the rear surface,
wherein a base via hole having an area that is equal to or less than an area of the base diffusion region is in the base diffusion region of the insulation film.

13. The solar cell of claim 1, wherein the base diffusion region comprises:
a first base diffusion region; and
a second base diffusion region near the first base diffusion region,
wherein the insulation gap has an auxiliary insulation gap that extends in a direction of the second base diffusion region from the first base diffusion region.

14. The solar cell of claim 13, further comprising:
an insulation film on the rear surface; and
a base contact electrode comprising:
a stem in a base via hole exposing at least a portion of the base diffusion region; and
an extending part extending over the insulation film at the stem, and overlapping the auxiliary insulation gap.

15. The solar cell of claim 13, wherein a width of the auxiliary insulation gap is greater than a width of a main insulation gap of the insulation gap.

16. The solar cell of claim 15, wherein the width of the auxiliary insulation gap is equal to or less than a sum of a width of the first base diffusion region and twice the width of the main insulation gap.

17. The solar cell of claim 15, wherein the width of the auxiliary insulation gap is equal to or less than a sum of a width of the first base diffusion region and 200 μm.

18. The solar cell of claim 13, further comprising:
a plurality of main insulation gaps; and
a plurality of auxiliary insulation gaps that are continuously located between one of the main insulation gaps adjacent the first base diffusion region and another one of the main insulation gaps adjacent the second base diffusion region.

19. The solar cell of claim 13, further comprising:
a plurality of main insulation gaps; and
a plurality of auxiliary insulation gaps that are discontinuously located between one of the main insulation gaps adjacent the first base diffusion region and another one of the main insulation gaps adjacent the second base diffusion region.

20. The solar cell of claim 13, further comprising a plurality of emitter diffusion regions, wherein the auxiliary insulation gap is between neighboring ones of the emitter diffusion regions.
